(19) United States
(12) Patent Application Publication
(10) Pub. No.: US 2018/0315458 A1
(43) Pub. Date: Nov. 1, 2018

(54) VOLTAGE SYSTEM AND METHOD FOR OPERATING THE SAME

(71) Applicant: NANYA TECHNOLOGY CORPORATION, NEW TAIPEI CITY (TW)

(72) Inventor: Ting-Shuo HSU, NEW TAIPEI CITY (TW)

(21) Appl. No.: 15/581,764

(22) Filed: Apr. 28, 2017

(51) Int. Cl. G11C 5/14

(52) U.S. Cl. CPC G11C 5/145

(57) ABSTRACT

The present disclosure provides a voltage system and a method for operating the same, and the voltage system provides a pump voltage serving as a supply voltage for electrical components of a memory device. The voltage system includes a first pump device and a second pump device. The second pump device is prepared as a spare pump device. The first pump device provides the supply voltage without the second pump device when a voltage level of the supply voltage is greater than a reference voltage level. A combination of the first pump device and the second pump device together provides the supply voltage when the voltage level of the supply voltage is less than the reference voltage level.

### TECHNICAL FIELD

The present disclosure relates to a voltage system, and more particularly, to a voltage system providing a pump voltage serving as a supply voltage for electrical components of a memory device and a method for operating the same.

### DISCUSSION OF THE BACKGROUND

Voltage regulators (VRs) are generally used in power delivery applications in which an input voltage needs to be transformed to an output voltage in ratios that range from smaller than unity to greater than unity.

This Discussion of the Background section is provided for background information only. The statements in this Discussion of the Background are not an admission that the subject matter disclosed in this section constitutes prior art to the present disclosure, and no part of this section may be used as an admission that any part of this application, including this Discussion of the Background section, constitutes prior art to the present disclosure.

### SUMMARY

One aspect of the present disclosure provides a voltage system. The voltage system includes a first pump device and a second pump device. The second pump device is prepared as a spare pump device. The first pump device provides the supply voltage without the second pump device when a voltage level of the supply voltage is greater than a reference voltage level. A combination of the first pump device and the second pump device together provides the supply voltage when the voltage level of the supply voltage is less than the reference voltage level.

In some embodiments, the second pump device is configured to receive a signal and, in response to the received signal, provide the supply voltage in combination with the first pump device.

In some embodiments, the first pump device is configured to receive the signal and, in response to the received signal, provide the supply voltage.

In some embodiments, the voltage system further includes a switch device configured to allow the signal to transmit to the second pump device when the voltage level of the supply voltage is less than the reference voltage level.

In some embodiments, the switch device is further configured to compare the voltage level of the supply voltage to the reference voltage level.

In some embodiments, the second pump device is directly coupled to the switch device.

In some embodiments, the signal is a second signal. The voltage system further includes: a first oscillator configured to provide the first pump device with a first signal, wherein the first pump device is configured to, in response to the first signal, provide the supply voltage; and a second oscillator, independent of the first oscillator, configured to provide the second pump device with the second signal when the voltage level of the supply voltage is less than the reference voltage level.

In some embodiments, the second oscillator is identical to the first oscillator, and the first signal and the second signal, provided by the first oscillator and the second oscillator, respectively, have the same frequency.

In some embodiments, the frequency of the second signal provided by the second oscillator is different from the frequency of the first signal provided by the first oscillator.

In some embodiments, the frequency of the second signal provided by the second oscillator is greater than the frequency of the first signal provided by the first oscillator.

In some embodiments, the voltage system further includes a sensing device, independent of the second oscillator, configured to activate the second oscillator when the voltage level of the supply voltage is less than the reference voltage level.

In some embodiments, the sensing device is further configured to compare the voltage level of the supply voltage to the reference voltage level.

In some embodiments, the second pump device is directly coupled to the second oscillator.

In some embodiments, the sensing device is a second sensing device. The voltage system further includes: a first sensing device configured to activate the first oscillator when the voltage level of the supply voltage is less than a basis reference voltage level, wherein the basis reference voltage level is greater than the reference voltage level.

Another aspect of the present disclosure provides a voltage system. The voltage system includes an oscillator, a first pump device and a second pump device. The oscillator configured to provide a signal when a voltage level of the supply voltage is less than a reference voltage level. The second pump device is prepared as a spare pump device. The second pump device is configured to receive the signal, and in response to the receive signal provides the supply voltage in combination with the first pump device. The first pump device provides the supply voltage without the second pump device when a voltage level of the supply voltage is greater than the reference voltage level.

In some embodiments, the second pump device is directly coupled to the oscillator.

In some embodiments, the voltage system further includes a sensing device configured to activate the oscillator when the voltage level of the supply voltage is less than the reference voltage level.

In some embodiments, the sensing device is further configured to compare the voltage level of the supply voltage to the reference voltage level.

Another aspect of the present disclosure provides a method for operating a voltage system. The method includes providing a supply voltage of the voltage system by a first pump device of the voltage system without using a second pump device until a voltage level of the supply voltage is less than a reference voltage level; and providing the supply voltage by a combination of the first pump device, and the second pump device serving as a spare pump device when the voltage level of the supply voltage is less than a reference voltage level.

In some embodiments, the method further includes providing a signal to the second pump device when the voltage level of the supply voltage is less than a reference voltage level, thereby activating the second pump device.

In the present disclosure, by adding to the first layout additional conductive layers, such as a metal-1 layer, a metal-2 layer, or a combination thereof, wherein the additional conductive layers are coupled to the second pump device 214 for transmitting the signal CLK to the second pump device 214, it can be assured that the second pump device 214 is utilized to provide the supply voltage Vpump. Therefore, usage of components in the voltage system 20 is relatively efficient.

Moreover, in a scenario, the supply voltage Vpump may drop drastically, from example, from about 3.0V to about 1.5V, which is less than not only the basis reference voltage level Vref0 but also the reference voltage level Vref. As such, the second pump device 214 is activated, such that a combination of the second pump device 214 and the first pump device 212 together provides the supply voltage Vpump. Using both the first pump device 212 and the second pump device 214, a relatively short time is required to increase the supply voltage Vpump from a drastically reduced level of about 1.5V back to a desired level of about 3.0V.

In contrast, in some comparative embodiments, in a scenario, the supply voltage Vpump of the voltage system 10 may drop drastically. For example, it is assumed that the supply voltage Vpump serves as a supply voltage for a load. When an operation mode of the load is changed from a light-load mode to a heavy-load mode, the supply voltage Vpump may drop drastically, for example, from about 3.0V to about 1.5V. In such scenario, a relatively long time is required to increase the supply voltage Vpump using only the first pump device 112 from a drastically reduced level of about 1.5V back to a desired level of about 3.0V.

Moreover, in the scenario of a comparative embodiment, if the voltage level of the supply voltage Vpump provided only by the first pump device 112 is sufficient to achieve the desired voltage level, there is no need to redesign the layout of the voltage system 10. In this way, referring to FIG. 1, the second pump device 114 is arranged in the system but is not utilized, and therefore usage of components in such voltage system 10 is not efficient.

The foregoing has outlined rather broadly the features and technical advantages of the present disclosure in order that the detailed description of the disclosure that follows may be better understood. Additional features and advantages of the disclosure are described hereinafter, and form the subject of the claims of the disclosure. It should be appreciated by those skilled in the art that the conception and specific embodiment disclosed may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a block diagram of a comparative voltage system prior to being redesigned by using a metal-option approach, in accordance with a comparative embodiment of the present disclosure.

FIG. 2 is a block diagram of the comparative voltage system of FIG. 1 after being redesigned by using a metal-option approach, in accordance with a comparative embodiment of the present disclosure.

FIG. 3 is a block diagram of a voltage system, in accordance with an embodiment of the present disclosure.

FIG. 4 is a block diagram illustrating an operation of the voltage system of FIG. 3, in accordance with an embodiment of the present disclosure.

FIG. 5 is a block diagram illustrating another operation of the voltage system of FIG. 3, in accordance with an embodiment of the present disclosure.

FIG. 6 is a block diagram of another voltage system, in accordance with an embodiment of the present disclosure.

FIG. 7 is a block diagram illustrating an operation of the voltage system of FIG. 6, in accordance with an embodiment of the present disclosure.

FIG. 8 is a block diagram illustrating another operation of the voltage system of FIG. 6, in accordance with an embodiment of the present disclosure.

FIG. 9 is a flow diagram of a method for operating a voltage system, in accordance with an embodiment of the present disclosure.

### DETAILED DESCRIPTION

Embodiments, or examples, of the disclosure illustrated in the drawings are now described using specific language. It shall be understood that no limitation of the scope of the disclosure is thereby intended. Any alteration or modification to the described embodiments, and any further applications of principles described in this document, are to be considered as normally occurring to one of ordinary skill in the art to which the disclosure relates. Reference numerals may be repeated throughout the embodiments, but this does not necessarily require that feature(s) of one embodiment apply to another embodiment, even if they share the same reference numeral.

It shall be understood that when an element is referred to as being “connected to” or “coupled with” another element, it may be directly connected to or coupled to the other element, or intervening elements may be present.

It shall be understood that, although the terms first, second, third, etc. may be used herein to describe various elements, components, regions, layers or sections, these elements, components, regions, layers or sections should not be limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It shall be further understood that the terms “comprises” and “comprising,” when used in this specification, specify the presence of stated features, integers, steps, operations, elements, or components, but do not preclude the presence or addition of one or more other features, integers, steps, operations, elements, components, or groups thereof.

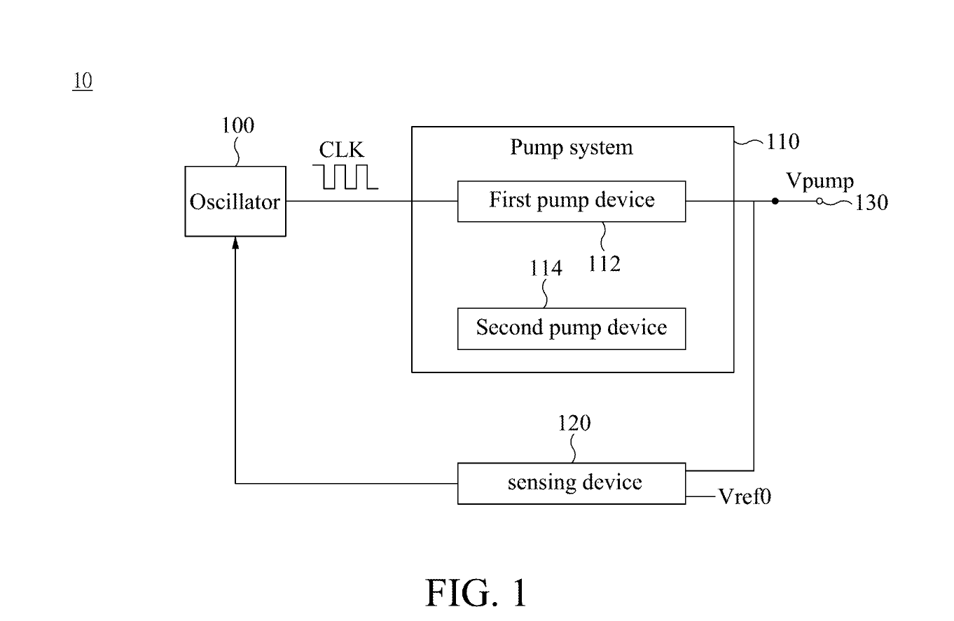

FIG. 1 is a block diagram of a comparative voltage system prior to being redesigned by using a metal-option approach, in accordance with a comparative embodiment of the present disclosure. Referring to FIG. 1, the voltage system 10 includes an oscillator 100, a pump system 110 including a first pump device 112 and a second pump device 114, and a sensing device 120.

The oscillator 100 functions to provide a signal CLK to the first pump device 112, thereby activating the first pump device 112. In an embodiment, the signal CLK includes a clock signal.

The first pump device 112 functions to provide a supply voltage Vpump of the voltage system 10 in response to the signal CLK. In further detail, the first pump device 112 charges a capacitor (not shown) coupled to an output port 130 of the voltage system 10, thereby increasing the supply voltage Vpump. The first pump device 112, for clarity of discussion, is identified and illustrated as a single device. However, the first pump device 112 may alternatively represent an assembly including a plurality of first pump devices 112. In an embodiment, the supply voltage Vpump serves as a supply voltage of electrical components of a memory device including the voltage system 10.

The second pump device 114 is configured to have the same function as the first pump device 112, while the second pump device 114 serves as a spare pump device. The term “spare pump device” refers to a pump device that is not coupled to other devices such as the oscillator 100 in a first layout but may be coupled to other devices in an amended version of the first layout if it is required. Since FIG. 1 depicts the comparative voltage system 10 prior to the comparative voltage system 10 being redesigned, the layout associated with the block diagram shown in FIG. 1 can be deemed as the first layout. In further detail, in the first layout of the voltage system 10, there are no conductive layers, such as a metal-1 layer, a metal-2 layer, or a combination thereof, arranged to couple the spare pump device to other devices such as the oscillator 100. Therefore, as illustrated, due to limitation of the layout, the signal CLK is not available to the second pump device 114. As a result, the second pump device 114 is kept deactivated, and therefore is not able to provide the supply voltage Vpump. Moreover, the second pump device 114, for clarity of discussion, is identified and illustrated as a single device. However, the second pump device 114 may alternatively represent an assembly including a plurality of second pump devices 114.

The sensing device 120 functions to sense a voltage level of the supply voltage Vpump, and to compare the voltage level of the supply voltage Vpump to a basis reference voltage level Vref0. In an embodiment, the basis reference voltage level Vref0 is 2.9 volts (V). Based on the comparison result, the sensing device 120 functions to either activate or deactivate the oscillator 100.

Given that the basis reference voltage level Vref0 is 2.9V. In operation, when the voltage level of the supply voltage Vpump is 2.8V and therefore is less than the basis reference voltage level Vref0 of 2.9V, the sensing device 120 activates the oscillator 100. The oscillator 100 provides the first pump device 112 with the signal CLK. The first pump device 112 is therefore activated in response to the signal CLK, and charges the capacitor. As a result, the first pump device 112 provides the supply voltage Vpump.

Alternatively, when the voltage level of the supply voltage Vpump is 3.0V and therefore is greater than the basis reference voltage level Vref0 of 2.9V, the sensing device 120 deactivates the oscillator 100. The oscillator 100 does not provide the first pump device 112 with the signal CLK. The first pump device 112 is therefore deactivated, and does not charge the capacitor. As a result, the first pump device 112 does not provide the supply voltage Vpump.

In a scenario, the supply voltage Vpump of the voltage system 10 may drop drastically. For example, it is assumed that the supply voltage Vpump serves as a supply voltage for a load. When an operation mode of the load is changed from a light-load mode to a heavy-load mode, the supply voltage Vpump may drop drastically, from example, from about 3.0V to about 1.5V. In such scenario, a relatively long time is required to increase the supply voltage Vpump using only the first pump device 112 from a drastically reduced voltage level of about 1.5V back to a desired voltage level of about 3.0V.

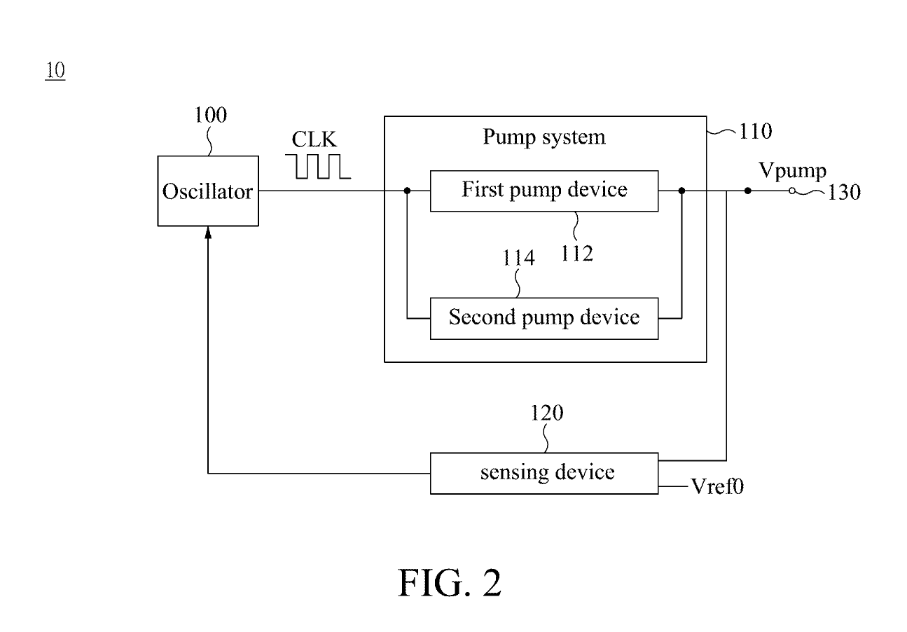

Moreover, after the voltage system 10 is manufactured as a final product, a voltage level of the supply voltage Vpump will be tested to check whether the voltage level of the supply voltage Vpump reaches a desired voltage level. If the voltage level of the supply voltage Vpump does not reach the desired voltage level because, for example, some of the first pump devices 112 fail, a redesigned layout of the voltage system 10 would be required. The redesigned layout of the voltage system 10 will be described in detail with reference to FIG. 2.

FIG. 2 is a block diagram of the comparative voltage system of FIG. 1 after being redesigned by using a metal-option approach, in accordance with a comparative embodiment of the present disclosure. The layout associated with the block diagram shown in FIG. 2 can be deemed as the amended version of the first layout. In a redesigned layout of the voltage system 10, some conductive layers, such as a metal-1 layer, a metal-2 layer, or a combination thereof, are formed. Such conductive layers are used to couple the spare pump device such as the second pump device 114 to the oscillator 100. Referring to FIG. 2, as illustrated, with the conductive layers, the second pump 114 is coupled to the oscillator 100, and the signal CLK is therefore provided to the second pump device 114. As a result, the second pump device 114 is able to be activated in response to the signal CLK, and therefore is able to provide the supply voltage Vpump in combination with the first pump device 112. Since the second pump device 114 has the same function as the first pump device 112 and is able to receive the signal CLK, the second pump device is deemed as a replacement of the failed first pump device 112. In this way, with the involvement of the second pump device 114, the desired voltage level may be reached.

However, in the scenario as previously discussed, the second pump device 114 is still not utilized with respect to reducing time for increasing the drastically reduced voltage level to the desired voltage level.

Moreover, referring back to FIG. 1, if the voltage level of the supply voltage Vpump, provided only by the first pump device 112 without using another pump device, is sufficient to reach the desired voltage level, there is no need to redesign the layout of the voltage system 10. In this way, referring to FIG. 1, the second pump device 114 is arranged in the system but is not utilized, and therefore usage of components in such voltage system 10 is not efficient.

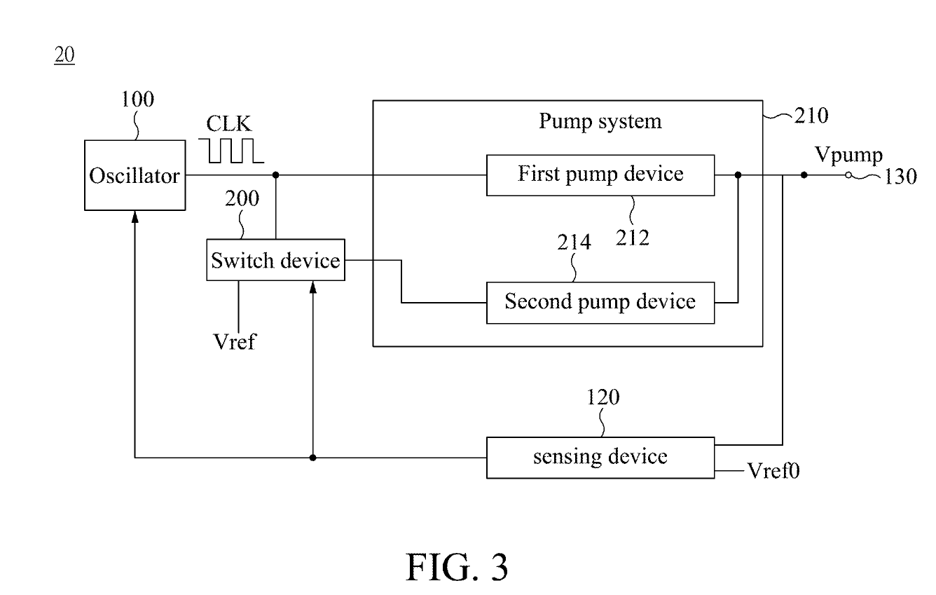

FIG. 3 is a block diagram of a voltage system 20, in accordance with an embodiment of the present disclosure. Referring to FIG. 3, the voltage system 20 is similar to the voltage system 10 described and illustrated with reference to FIG. 1 except that the voltage system 20 includes a pump system 210 including a first pump device 212 and a second pump device 214, and a switch device 200. The first pump device 212 and the second pump device 214 are similar to the first pump device 112 and the second pump device 114 described and illustrated with reference to FIG. 1, respectively, and therefore some detailed descriptions thereof are omitted herein.

The first pump device 212 functions to receive the signal CLK from the oscillator 100, and to provide the supply voltage Vpump in response to the received signal CLK.

The second pump device 214 is prepared as a spare pump device. However, unlike the second pump device 114 of FIG. 1, which is, in the amended version of the first layout (i.e., as shown in FIG. 2), arranged to be coupled to the oscillator 100 for use as required, the second pump device 214 in the present invention is arranged to be coupled to the switch device 200 in a first layout, as shown in FIG. 3. In an embodiment, the second pump device 214 is directly coupled to the switch device 200. Therefore, in the present disclosure, although the second pump device 214 is prepared as a spare pump device, the second pump device 214 is able to provide the supply voltage Vpump in combination with the first pump device 212.

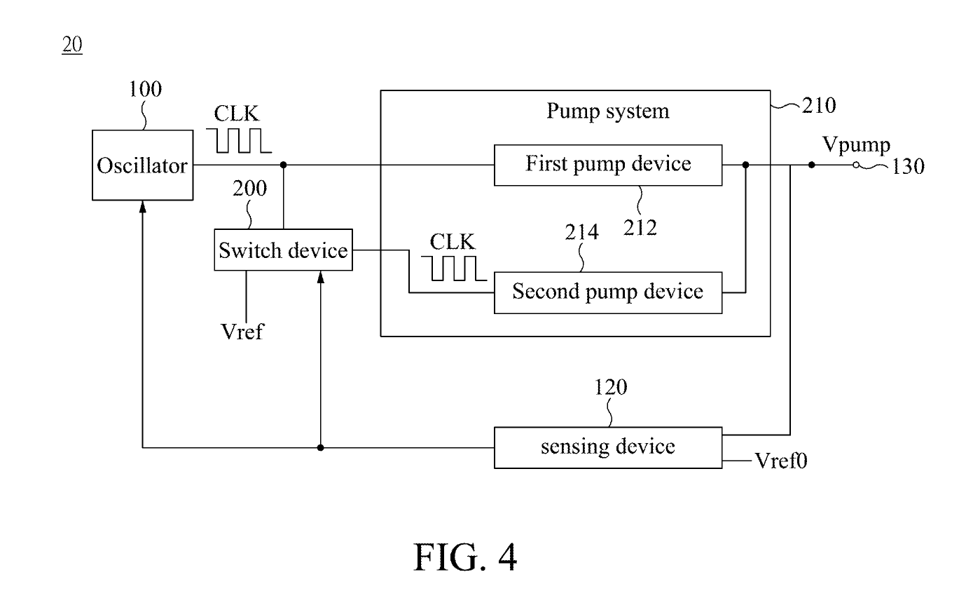

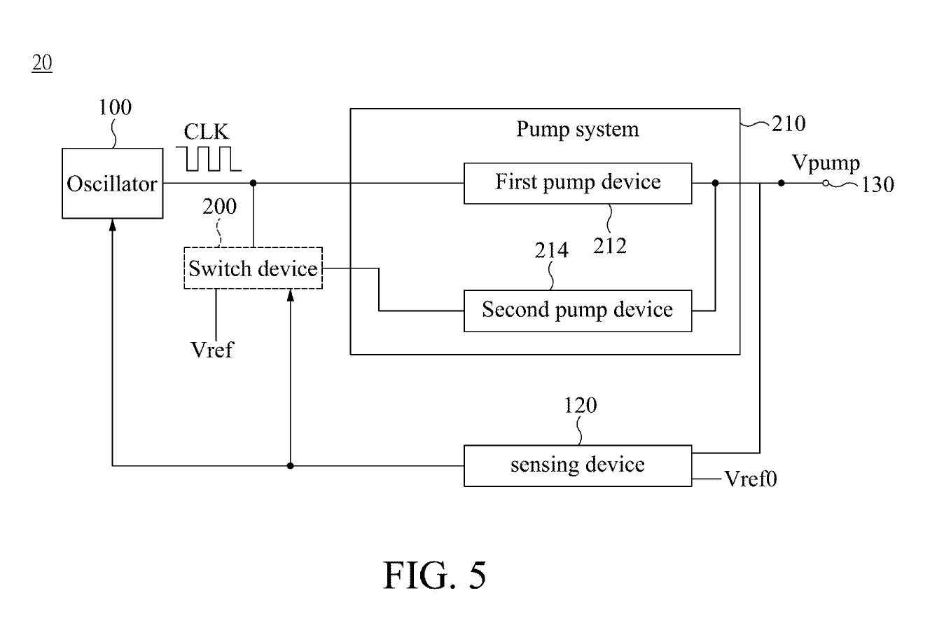

The switch device 200, coupled to the second pump device 214, functions to compare the sensed voltage level of the supply voltage Vpump from the sensing device 120 to the reference voltage level Vref. In addition, the switch device 200 based on the comparison result determines whether to allow the signal CLK to transmit to the second pump device 214, thereby either activating or deactivating the second pump device 214, which will be described in detail with reference to FIGS. 4 and 5. In an embodiment, the switch device 200 includes a transistor serving as a switch between the oscillator 100 and the second pump device 214.

In an embodiment, the transistor includes a metal-oxide-semiconductor field-effect transistor (MOSFET). In another embodiment, the transistor includes a high voltage MOSFET capable of operating at 700 volts or above. Alternatively, the transistor includes bipolar junction transistors (BJTs), complementary MOS (CMOS) transistors, or the like. In one or more embodiments, the transistor includes a power field-effect transistor (FET), such as a double-diffused metal-oxide-semiconductor (DMOS) transistor. In yet other embodiments, the transistor includes another suitable device, such as an insulated-gate bipolar transistor (IGBT), a field effect transistor (FET), or the like. In the present embodiment, the transistor includes a p-type metal-oxide-semiconductor (PMOS) field-effect transistor. In another embodiment, the transistor includes an n-type metal-oxide-semiconductor (NMOS) field-effect transistor.

In the present embodiment, by adding to the first layout additional conductive layers, such as a metal-1 layer, a metal-2 layer, or a combination thereof, wherein the additional conductive layers are coupled to the second pump device 214 for transmitting the signal CLK to the second pump device 214, it can be assured that the second pump device 214 is utilized to provide the supply voltage Vpump. Therefore, usage of components in the voltage system 20 is relatively efficient.

FIG. 4 is a block diagram illustrating an operation of the voltage system 20 of FIG. 3, in accordance with an embodiment of the present disclosure. Referring to FIG. 4, the switch device 200 compares the sensed voltage level of the supply voltage Vpump from the sensing device 120 to the reference voltage level Vref. The comparison result indicates that the sensed voltage level of the supply voltage Vpump is less than the reference voltage level Vref. Accordingly, the switch device 200 allows the signal CLK to pass to the second pump device 214. The second pump device 214 receives the signal CLK, and is activated in response to the received signal CLK. As such, the second pump device 214, in combination with the first pump device 212, provides the supply voltage Vpump.

As previously mentioned, the basis reference voltage level Vref0 is greater than the reference voltage level Vref0. It is assumed that the basis reference voltage level Vref0 is about 2.9V, and the reference voltage level Vref is about 2.5V. In a scenario, the supply voltage Vpump serves as a supply voltage for a load. When an operation mode of the load is changed from a light-load mode to a heavy-load mode, the supply voltage Vpump may drop drastically, from example, from about 3.0V to about 1.5V, which is less than not only the basis reference voltage level Vref0 but also the reference voltage level Vref. Since the drastically reduced voltage of about 1.5V is less than the reference voltage level Vref of about 2.5V, the second pump device 214 is activated, such that the combination of the second pump device 214 and the first pump device 212 together provides the supply voltage Vpump. In further detail, the first pump device 212 and the second pump device 214 function together to charge a capacitor coupled to the output port 130 of the voltage system 20. Therefore, under such circumstances, a relatively short time is required to increase the supply voltage Vpump by both the first pump device 212 and the second pump device 214 from a drastically reduced level of about 1.5V back to a desired level of about 3.0V.

FIG. 5 is a block diagram illustrating another operation of the voltage system 20 of FIG. 3, in accordance with an embodiment of the present disclosure. Referring to FIG. 5, the switch device 200 compares the sensed voltage level of the supply voltage Vpump from the sensing device 120 to the reference voltage level Vref. The comparison result indicates that the sensed voltage level of the supply voltage Vpump is greater than the reference voltage level Vref. Accordingly, the switch device 200 prevents the signal CLK from passing to the second pump device 214. The second pump device 214 does not receive the signal CLK, and therefore is not activated. The second pump device 214 does not provide the supply voltage Vpump. As such, the first pump device 212 provides the supply voltage Vpump without the use of another pump device.

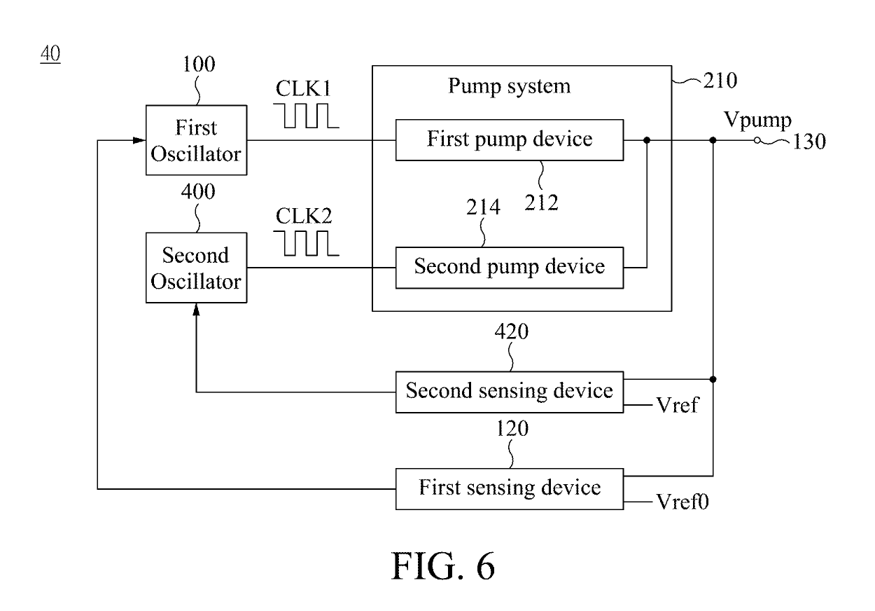

FIG. 6 is a block diagram of another voltage system 40, in accordance with an embodiment of the present disclosure. Referring to FIG. 6, the voltage system 40 is similar to the voltage system 20 described and illustrated with reference to FIG. 2 except that, for example, the voltage system 40 includes a second oscillator 400 and a second sensing device 420. Moreover, for convenience of discussion, the oscillator 100 of FIG. 1 is renamed and renumbered as the first oscillator 100; the signal CLK of FIG. 1 is renamed and renumbered as the first signal CLK; and the sensing device 120 is renamed as the first sensing device 120.

The second oscillator 400, independent of the first oscillator 100 and coupled to the second pump device 214, functions to provide the second pump device 214 with a second signal CLK2. In an embodiment, the second oscillator 400 is directly coupled to the second pump device 214. Moreover, in an embodiment, the second oscillator 400 is identical to the first oscillator 100, and therefore the first signal CLK1 and second signal CLK2 have the same frequency. For example, a layout of the second oscillator 400 is copied from a layout of the first oscillator 100. Since the second oscillator 400 is identical to the first oscillator 100, efficient circuit design is facilitated. There is no need to redesign the second oscillator 400. In some embodiments, the first signal CLK1 and second signal CLK2 have different frequencies. In a further embodiment, a frequency of the second signal CLK2 is greater than that of the first signal CLK1. As such, a relatively short time is required to increase the reduced voltage level of the supply voltage Vpump back to the desired voltage level.

In the present embodiment, by adding to a first layout of the voltage system 40 additional conductive layers, such as a metal-1 layer, a metal-2 layer, or a combination thereof, wherein the additional conductive layers are coupled to the second pump device 214 for transmitting the second signal CLK2 to the second pump device 214, it can be assured that the second pump device 214 is utilized to provide the supply voltage Vpump. Therefore, usage of components in the voltage system 40 is relatively efficient.

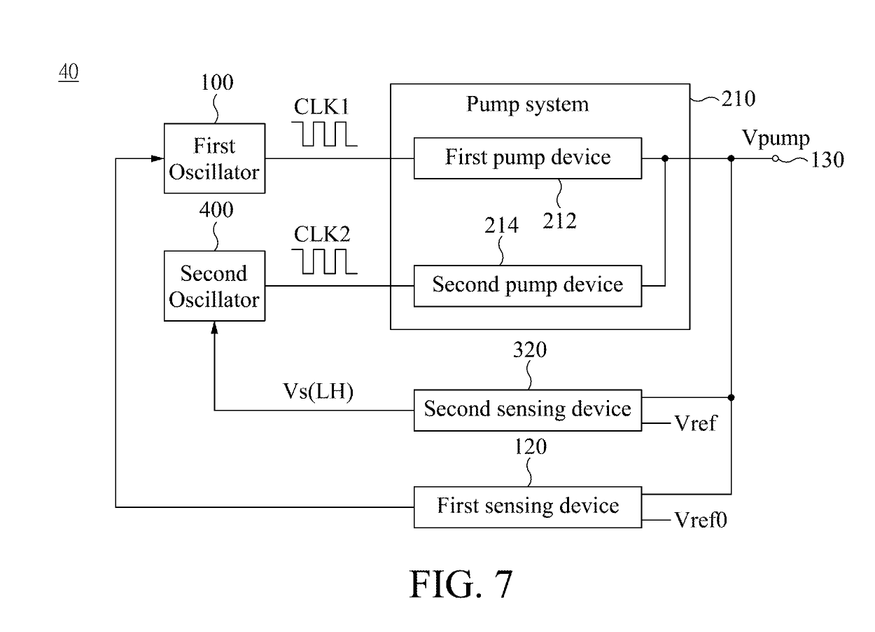

FIG. 7 is a block diagram illustrating an operation of the voltage system 40 of FIG. 6, in accordance with an embodiment of the present disclosure. Referring to FIG. 7, the second sensing device 320 compares the voltage level of the supply voltage Vpump to the reference voltage level Vref. The comparison result indicates that the voltage level of the supply voltage Vpump is greater than the reference voltage level Vref. The second sensing device 320 provides the second oscillator 400 with a signal Vs having a first logic level (LH), for example, a logical high, thereby activating the second oscillator 400. The second oscillator 400 provides the second signal CLK2 to the second pump device 214. The second pump device 214 receives the second signal CLK2, and is activated in response to the received second signal CLL2. As such, the second pump device 214 provides the supply voltage Vpump in combination with the first pump device 212.

As previously mentioned, the supply voltage Vpump may drop drastically, from example, from about 3.0V to about 1.5V, which is less than not only the basis reference voltage level Vref0 but also the reference voltage level Vref. As such, the second pump device 214 is activated, such that the combination of the second pump device 214 and the first pump device 212 together provides the supply voltage Vpump. Therefore, under such circumstances, a relatively short time is required using both the first pump device 212 and the second pump device 214 to increase the supply voltage Vpump from a drastically reduced level of about 1.5V back to a desired level of about 3.0V.

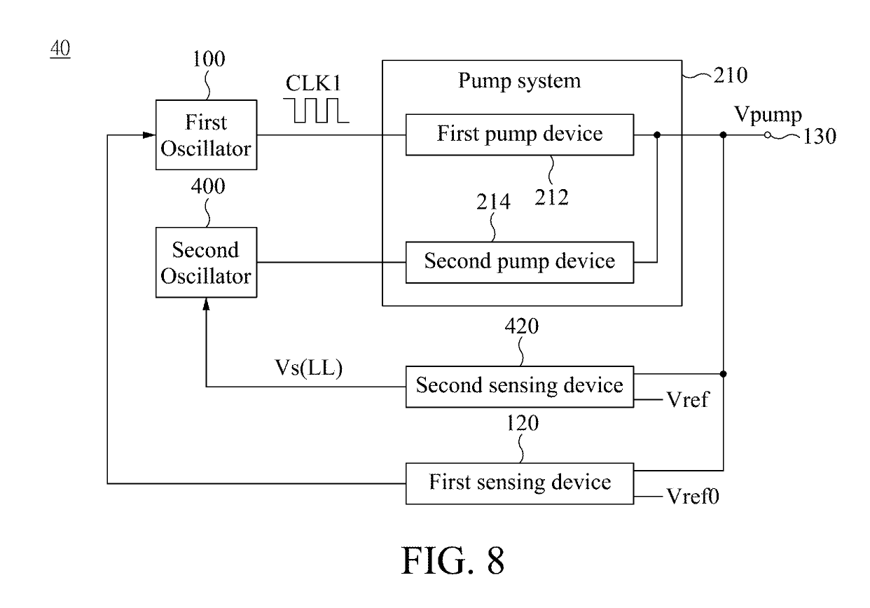

FIG. 8 is a block diagram illustrating another operation of the voltage system 40 of FIG. 6, in accordance with an embodiment of the present disclosure. Referring to FIG. 8, the second sensing device 420 compares the voltage level of the supply voltage Vpump to the reference voltage level Vref. The comparison result indicates that the voltage level of the supply voltage Vpump is greater than the reference voltage level Vref. Accordingly, the second sensing device 420 provides the second oscillator with the signal Vs having a second logic level LL, for example logical low, thereby deactivating the second oscillator 400. The second oscillator 400 does not provide the second signal CLK2 to the second pump device 214. The second pump device 214 is deactivated. As such, the first pump device 212 provides the supply voltage Vpump without use of another pump device.

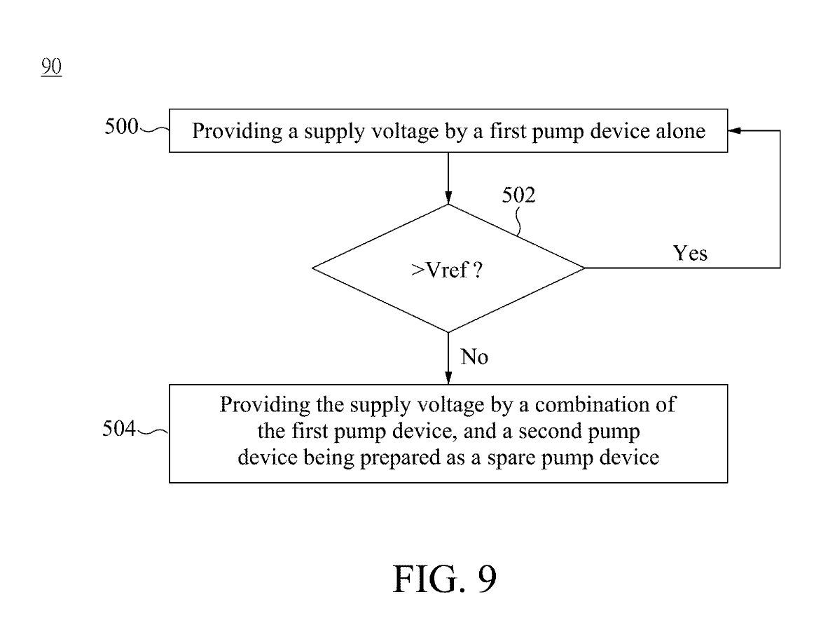

FIG. 9 is a flow diagram of a method 90 for operating a voltage system, in accordance with an embodiment of the present disclosure. Referring to FIG. 9, the method 90 includes operations 500, 502 and 504. The method 90 begins with operation 500, in which a supply voltage is provided by a first pump device without using a second pump device serving as a spare pump device. For example, referring back to FIG. 3, the supply voltage Vpump of the voltage system 20 is provided by the first pump device 212 without using the second pump device 214.

The method 90 then continues with operation 502, in which it is determined whether a voltage level of the supply voltage is greater than a reference voltage level. If affirmative, the method returns to operation 500. If negative, the method proceeds to operation 504, in which the supply voltage is provided by a combination of the first pump device and a second pump device. In the present disclosure, although the second pump device is prepared as a spare pump device, the second pump device is able to provide the supply voltage Vpump in combination with the first pump device.

In the present disclosure, by adding to the first layout additional conductive layers, such as a metal-1 layer, a metal-2 layer, or a combination thereof, wherein the additional conductive layers are coupled to the second pump device 214 for transmitting the signal CLK to the second pump device 214, it can be assured that the second pump device 214 is utilized to provide the supply voltage Vpump. Therefore, usage of components in the voltage system 20 is relatively efficient.

Moreover, in a scenario, the supply voltage Vpump may drop drastically, from example, from about 3.0V to about 1.5V, which is less than not only the basis reference voltage level Vref0 but also the reference voltage level Vref. As such, the second pump device 214 is activated, such that the combination of the second pump device 214 and the first pump device 212 together provides the supply voltage Vpump. Using both the first pump device 212 and the second pump device 214, a relatively short time is required to increase the supply voltage Vpump from a drastically reduced level of about 1.5V back to a desired level of about 3.0V.

In contrast, in some comparative embodiments, in a scenario, the supply voltage Vpump of the voltage system 10 may drop drastically. For example, it is assumed that the supply voltage Vpump serves as a supply voltage for a load. When an operation mode of the load is changed from a light-load mode to a heavy-load mode, the supply voltage Vpump may drop drastically, from example, from about 3.0V to about 1.5V. In such scenario, a relatively long time is required using only the first pump device 112 to increase the supply voltage Vpump from a drastically reduced level of about 1.5V back to a desired level of about 3.0V.

Moreover, in such comparative embodiments, if the voltage level of the supply voltage Vpump provided only by the first pump device 112 is sufficient to provide the desired voltage level, there is no need to redesign the layout of the voltage system 10. In such arrangement, referring to FIG. 1, the second pump device 114 is arranged in the system but is not utilized, and therefore usage of components in such voltage system 10 is not efficient.

One aspect of the present disclosure provides a voltage system. The voltage system includes a first pump device and a second pump device. The second pump device is prepared as a spare pump device. The first pump device provides the supply voltage without the second pump device when a voltage level of the supply voltage is greater than a reference voltage level. A combination of the first pump device and the second pump device together provides the supply voltage when the voltage level of the supply voltage is less than the reference voltage level.

Another aspect of the present disclosure provides a voltage system. The voltage system includes an oscillator, a first pump device and a second pump device. The oscillator configured to provide a signal when a voltage level of the supply voltage is less than a reference voltage level. The second pump device is prepared as a spare pump device. The second pump device is configured to receive the signal, and in response to the receive signal provides the supply voltage in combination with the first pump device. The first pump device provides the supply voltage without the second pump device when a voltage level of the supply voltage is greater than the reference voltage level.

Another aspect of the present disclosure provides a method of operating a voltage system. The method includes providing a supply voltage of the voltage system by a first pump device of the voltage system without using a second pump device until a voltage level of the supply voltage is less than a reference voltage level; and providing the supply voltage by a combination of the first pump device, and the second pump device serving as a spare pump device when the voltage level of the supply voltage is less than a reference voltage level.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A voltage system providing a supply voltage, comprising:
a first pump device;
a second pump device being prepared as a spare pump device; and
a switch device, directly coupled to the second pump device, having a reference voltage level;
wherein the first pump device provides the supply voltage without the second pump device when the switch device compares the voltage level of the supply voltage to the reference voltage level and the voltage level of the supply voltage is greater than the reference voltage level, and
wherein a combination of the first pump device and the second pump device together provides the supply voltage when the switch device compares the voltage level of the supply voltage to the reference voltage level and the voltage level of the supply voltage is less than the reference voltage level.

2. The voltage system of claim 1, wherein the second pump device is configured to receive a signal and provide the supply voltage in combination with the first pump device in response to the received signal.

3. The voltage system of claim 2, wherein the first pump device is configured to receive the signal, and provide the supply voltage in response to the received signal.

4. The voltage system of claim 2, wherein the switch device configured to allow the signal to transmit to the second pump device when the voltage level of the supply voltage is less than the reference voltage level.

5-6. (canceled)

7. The voltage system of claim 2, wherein the signal is a second signal, the voltage system further comprising:
a first oscillator configured to provide the first pump device with a first signal, wherein the first pump device is configured to, in response to the first signal, provide the supply voltage; and
a second oscillator, independent of the first oscillator, configured to provide the second pump device with the second signal when the voltage level of the supply voltage is less than the reference voltage level.

8. The voltage system of claim 7, wherein the second oscillator is identical to the first oscillator, and the first signal provided by the first oscillator and the second signal provided by the second oscillator have the same frequency.

9. The voltage system of claim 7, wherein the frequency of the second signal provided by the second oscillator is different from that of the first signal provided by the first oscillator.

10. The voltage system of claim 9, wherein the frequency of the second signal provided by the second oscillator is greater than that of the first signal provided by the first oscillator.

11. The voltage system of claim 7, further comprising:
a sensing device, independent of the second oscillator, configured to activate the second oscillator when the voltage level of the supply voltage is less than the reference voltage level.

12. The voltage system of claim 11, wherein the sensing device is further configured to compare the voltage level of the supply voltage to the reference voltage level.

13. The voltage system of claim 7, wherein the second pump device is directly coupled to the second oscillator.

14. The voltage system of claim 11, wherein the sensing device is a second sensing device, the voltage system further comprising:
a first sensing device configured to activate the first oscillator when the voltage level of the supply voltage is less than a basis reference voltage level, wherein the basis reference voltage level is greater than the reference voltage level.

15. A voltage system providing a supply voltage, comprising:
an oscillator configured to provide a signal;
a first pump device;
a second pump device being prepared as a spare pump device; and
a switch device receiving the signal, wherein the switch device is directly coupled to the second pump device and compares the voltage level of the supply voltage to the reference voltage level;
wherein when the voltage level of the supply voltage is less than the reference voltage level, the switch device allows the signal to transmit to the second pump device; in response to the signal the second pump device provides the supply voltage in combination with the first pump device,
wherein the first pump device provides the supply voltage without the second pump device when the voltage level of the supply voltage is greater than the reference voltage level.

16. (canceled)

17. The voltage system of claim 15, further comprising:
a sensing device configured to activate the oscillator when the voltage level of the supply voltage is less than a basis reference voltage level.

18. The voltage system of claim 17, wherein the sensing device is further configured to compare the voltage level of the supply voltage to the basis reference voltage level.

19. A method for operating a voltage system, comprising:
providing a supply voltage of the voltage system by a first pump device of the voltage system without using a second pump device until a voltage level of the supply voltage is less than a reference voltage level which is predetermined in a switch device being directly coupled to the second pump device; and
providing the supply voltage by a combination of the first pump device, and the second pump device serving as a spare pump device when the voltage level of the supply voltage is less than a reference voltage level.

20. The method of claim 19, comprising:
inputting a signal to the second pump device when the voltage level of the supply voltage is less than a reference voltage level, thereby activating the second pump device.
